(19) United States
(12) Patent Application Publication
(10) Pub. No.: US 2004/0263362 A1
(43) Pub. Date: Dec. 30, 2004

(54) Coding method and device

(76) Inventor: Gijs J Van Den Enden, Veldhoven (NL)

Correspondence Address: BLANK ROME LLP, 600 NEW HAMPSHIRE AVENUE, N.W., WASHINGTON, DC, 20037, US

(21) Appl. No.: 10/488,998

(22) PCT Filed: Sep. 10, 2002
(86) PCT No.: PCT/GB02/04113

(30) Foreign Application Priority Data
Sep. 10, 2001 (EP) 01203389.0

(51) Int. Cl. H03M 5/00

(52) U.S. Cl. 341/58

(57) ABSTRACT

A method for converting a succession of data words into an output bit stream comprising a succession of code words uses a table of code words and associated next state values. For each data word the table provides a code word and associated next state value for each of a plurality of present state values. The code words are either of a first type that correspond to only one data word or of a second type that correspond to more than one data word. The next state value associated with each code word of the second type belongs to one of a first group of states. The next state values ensure that adjacent code words chosen in accordance with the next state values satisfy a run length constraint. Code words belonging to the first group of states can be identified by a unique bit structure. The method comprises the following steps: a) retrieving a data word; b) selecting the code words corresponding to the data word from the others of the plurality of present state values which meet the run length constraint and, if the present state value belongs to the first group of states, which also match the unique bit structure of the present state value; c) selecting, from the code words selected in step b), the encoded word that will cause the dc content of the output bit stream to be closest to zero; and d) placing the encoded word selected in step c) into the output bit stream.

### BACKGROUND OF THE INVENTION

This invention relates to a method and device for encoding a series of m-bit information words, where m is an integer, into a series of n-bit code words, where n is an integer greater than m, for subsequent modulation.

### DESCRIPTION OF THE PRIOR ART

Run length limited codes, generically designated as (d, k) codes, have been widely and successfully applied in modern magnetic and optical recording systems. Such codes, and means for implementing said codes, are described by K. A. Schouhamer Immink in the book entitled “Codes for Mass Data Storage Systems” (ISBN 90-74249-23-X, 1999).

Run length limited codes are extensions of earlier non return to zero recording codes, where recorded binary zeros are represented by no change in the magnetic flux of the recording medium, while recorded binary ones are represented by transitions from one direction of magnetic flux to the opposite direction.

In a (d, k) code, the above recording rules are maintained with the additional constraints that at least d binary zeros are recorded between successive binary ones, and no more than k binary zeros are recorded between successive binary ones.

The first constraint arises to obviate inter-symbol interference occurring due to pulse crowding of the reproduced transitions when a series of binary ones are contiguously recorded. The second constraint arises in recovering a clock from the reproduced data by “locking” a phase locked loop to the reproduced transitions. If there is too long an unbroken string of contiguous binary zeros with no interspersed binary ones the clock regenerating phase locked loop will fall out of synchronism.

In, for example, a (1,7) code there is at least one binary zero between recorded binary ones, and there are no more than seven recorded contiguous binary zeros between recorded binary ones.

The series of encoded bits is converted, via a modulo-2 integration operation, to a corresponding modulated signal formed by bit cells having a high or low signal value, a binary one bit being represented in the modulated signal by a change from a high to a low signal value or vice versa. A binary zero bit is represented by the lack of change of the modulated signal.

The minimum distance between consecutive transitions of the modulated signal is d+1 bit intervals and the maximum distance between consecutive transitions of the modulated signal is k+1 bit intervals.

In addition, the low-frequency components of the modulated signal should be kept as small as possible, and in particular the dc component should be zero.

A first reason for using such a dc-free signal is that recording channels are not normally responsive to low-frequency and dc components. The suppression of low-frequency components in the signal is also highly advantageous when the signal is read from an optical record carrier on which the signal is recorded in the track, because then continuous tracking control undisturbed by the recorded signal is possible. A good suppression of the low-frequency components leads to improved tracking with less disturbing audible noise.

A first example of the use of such signals to record and read an audio signal on an optical or magneto-optical record carrier can be found in U.S. Pat. No. 4,501,000. This describes the EFM (Eight-to-Fourteen Modulation) modulation system, which is used for recording information on Compact Discs (CD) or MiniDisc (MD).

The EFM modulated signal is obtained by converting a series of 8-bit information words into a series of 14-bit code words, and inserting 3 merging bits between consecutive code words.

Respective code words of 14 bits satisfy the (d,k) constraint where d=2 and k=10. That is to say that at least 2 and at most 10 binary zeros are placed between two consecutive binary ones. In order to satisfy the (d,k) constraint between code words, the 3-bit merging or coupling words are used.

The rate of the code is a parameter, which is a measure of its efficiency. It is the quotient of the number of bits in the information word and the number of bits required to represent said information word. In the EFM code, 8-bit information words are translated into 14+3=17 (including merging words), so that the rate of the EFM code equals 8/17.

A second example of the use of such a method to record and read a dc-free signal on an optical or magneto-optical record carrier can be found in U.S. Pat. No. 5,917,857. This relates to a method of converting a series of m-bit information words to a modulated signal. The method is often called EFMPlus.

Whereas EFM conversion uses a single static conversion table, EFMPlus conversion selects one conversion table from several available conversion tables according to specific rules each time a data word is presented for conversion, and uses the selected conversion table to convert the data word to a code word. Note that the use of a specified single conversion table is referred to as a “state” corresponding to that conversion table.

In EFMPlus there is a total of eight tables, grouped according to four states (coding states 1 to 4), with two tables (a main and a substitute) associated with each state. Each main conversion table contains all of the information words that can be expressed by eight bits (256 information words) and the 16-bit code words corresponding to each of these information words and each of the four encoder states. Each substitute conversion table contains 88 information words from (in binary notation) 00000000 to 01010111, and the 16-bit code words corresponding to each of the information words and each of the four encoder states. Both the main and substitute tables contain a next state indicator, having a value 1 to 4, which indicates the encoder state to be used in the next conversion. The method of selecting one of the code words from the eight conversion tables each time an information word is supplied is outlined below.

Assume the current encoder state equals s, and the information word to be converted equals i. If the information word to be converted is in the range 00000000 to 01010111 (0≦i<88), the corresponding code word can be selected from either the main table or the substitute table depending on which code word achieves maximum suppression of the low-frequency components of the corresponding modulated signal. If the information word to be converted is not within the above range, i>87, the main conversion table must be used, and a selection on the basis of maximum low-frequency suppression cannot be made. The code words in the main and substitute tables, representing the information words lying in the range 0<i<88 have substantially different effects on the low-frequency components in the modulated signal.

In the eight coding tables of EFMPlus, there are code words that correspond with only one information word. These code words are called code words of the first type. There is a one-to-one relationship between code words of the first type and corresponding information words. A second group of code words, called code words of the second type, correspond to two information words, namely two different information words are translated into the same code word. The ambiguity can be resolved by a decoder as follows.

The group of code words of the second type is either followed by a code word of state 2 or by a code word of state 3. However, the sets of code words belonging to coding states 2 and 3 are disjoint, i.e. they have no code words in common. Thus, the decoder can, by observing both the current code word and the upcoming code word and specifically by determining the state to which the upcoming code word belongs, that is either 2 or 3, uniquely establish the information word associated with the current code word.

The code words in states 2 and 3 have been compiled in such a way that observation of the first and thirteenth bit of the code words belonging to these states can be used to establish the related state of said code word. Therefore, an information word associated with a code word of the second type can be uniquely decoded by observing the present code word and the first and thirteenth bit of the upcoming code word.

U.S. Pat. No. 5,790,056 describes an improved method for selecting code words from the eight coding tables. The invention described in said patent disclosure is based on the notion that the decoder must observe the upcoming code word when the upcoming code word is either in State 2 or 3. If the upcoming code word is in State 1 or 4, then the decoder does not need to observe the upcoming code word.

When the encoder is in State 1, either of the code words from state 1 or state 4 associated with a given information word can be transmitted if the juxtaposition of the transmitted code word and the previously transmitted code word satisfies the prescribed (d,k) constraint. In a similar vein, when the encoder is in state 4, either of the code words from state 1 or 4 associated with a given information word can be transmitted if the juxtaposition of the transmitted code word and the previously transmitted code word satisfies the prescribed (d,k) constraint. This so-called state 1-4 swapping method provides a larger degree of freedom of selecting code words for the minimization of low-frequency components of the modulated signal.

While EFMPlus described in U.S. Pat. No. 5,917,857 and the coding method described in U.S. Pat. No. 5,790,056 both offer a factor of 17/16 improvement upon the EFM conversion method with respect to the achievable recording density and sufficient suppression of low-frequency components, they require excessive storage capacity for storing the main and substitute conversion tables.

### SUMMARY OF THE INVENTION

According to a first aspect of the invention, there is provided a method for converting a succession of data words into an output bit stream comprising a succession of code words using a table of code words and associated next state values and in which for each data word the table provides a code word and associated next state value for each of a plurality of present state values, the code words being either of a first type that correspond to only one data word or of a second type that correspond to more than one data word, the next state value associated with each code word of the second type belonging to one of a first group of states, the next state values ensuring that adjacent code words chosen in accordance with the next state values satisfy a run length constraint, and wherein code words belonging to the first group of states can be identified by a unique bit structure, the method comprising:

a. retrieving a data word;

b. selecting the code words corresponding to the data word for each of the plurality of present state values which meet the run length constraint and, if the present state value belongs to the first group of states, which also match the unique bit structure of the present state value;

c. selecting, from the code words selected in step b, the code word that will cause the dc content of the output bit stream to be closest to zero; and,

d. placing the code word selected in step c in to the output bit stream.

According to a second aspect of the present invention, an encoder for converting a succession of data words into an output bit stream comprising a succession of code words, comprises:

a. a data word input for receiving a data word;

b. a first memory for storing a table of code words and associated next state values and in which for each data word the table provides a code word and associated next state value for each of a plurality of present state values, the code words being either of a first type that correspond to only one data word or of a second type that correspond to more than one data word, the next state value associated with each code word of the second type belonging to one of a first group of states, the next state values ensuring that adjacent code words chosen in accordance with the next state values satisfy a run length constraint, and wherein code words belonging to the first group of states can be identified by a unique bit structure;

c. a selector for selecting the code words corresponding to the data word from the others of the plurality of present state values which meet the run length constraint and, if the present state value belongs to the first group of states, which also match the unique bit structure of the present state value;

d; a second memory for storing the code words selected in step c;

e. a running digital sum circuit for determining the running digital sum of the output bit stream and each of the code words stored in the second memory;

f. a selector for selecting that code word from the second memory that had the lowest running digital sum in step d; and,

g. an code word output for placing the code word in the output bit stream.

Hence, the invention provides a method and device for encoding a succession of input data words into an output bit stream suitable for recording on a recording medium, such as a Digital Versatile Disc (DVD), that can achieve high suppression of dc content of the output bit stream and does not require the storage of substitute tables. Advantageously, it is unnecessary to change the decoder equipment, since a bit stream encoded using the method according to the invention remains compatible with existing decoders.

In a preferred embodiment, the number of present state values and next state values is 4, and typically, these values fall in the range 1 to 4.

Furthermore, when the present state and next state values are in the range 1 to 4, the first group of states normally comprises the present state and next state values 2 and 3. In this case, the unique bit structure of code words corresponding to present state and next state values 2 or 3 is that at least two bits have a predetermined value. Preferably, the unique bit structure of code words corresponding to present state value 2 is that both first and thirteenth bits are zero. Similarly, the unique bit structure of code words corresponding to present state value 3 is preferably that at least one of the first and thirteenth bits is not zero.

Typically, the length of a data word is 8 bits and the length of a code word is sixteen bits.

The run length constraint is normally a (d, k) constraint as described with reference to the prior art. That is to say that the run length constraint is normally that between each binary one of the output bit stream there is at least a first number of binary zeros and no more than a second number of binary zeros. Typically, the first number is 2 and the second number is 10.

In a preferred embodiment, the code word that will cause the dc content of the output bit stream to be closest to zero is selected by calculating the running digital sum of the output bit stream and all code words meeting the run length constraint and, if the present state value belongs to the first group of states, matching the unique bit structure of the present state value.

A recording medium may be used to carry a bit stream converted according to the first aspect of the invention. Suitable recording media include Compact Disc (CD), Digital Versatile Disc (DVD) and MiniDisc (MD).

The running digital sum circuit of the encoder may comprise a memory storing a look up table in which an individual running digital sum is stored for each code word, a memory for storing the current running digital sum of the output bit stream and a direction flag for indicating whether the running digital sum is increasing or decreasing and an adder/subtracter for adding the individual running digital sum of a code word to the current running digital sum of the output bit stream or subtracting the individual running digital sum of a code word from the current running digital sum of the output bit stream according to the direction flag.

Typically, the memory also stores a direction change flag for each code word. In this case, the direction flag is inverted if the direction change flag is set, otherwise the direction flag remains unchanged.

Alternatively, the running digital sum circuit may comprise an up/down binary counter, the direction of counting of which is changed after detection of a binary one and the count value of which is incremented or decremented, as appropriate, by the detection of either a binary one or zero.

### BRIEF DESCRIPTION OF THE DRAWINGS

An example of an encoder and the encoding method according to the invention will now be described, with reference to the accompanying drawings, in which:

FIG. 1 shows an example of an encoder;

FIG. 2 shows a coding table in which the relationship between the information words and code words is established;

FIG. 3 shows a first implementation of a running digital sum circuit; and,

FIG. 4 shows a second implementation of a running digital sum circuit.

### DESCRIPTION OF THE PREFERRED EMBODIMENT

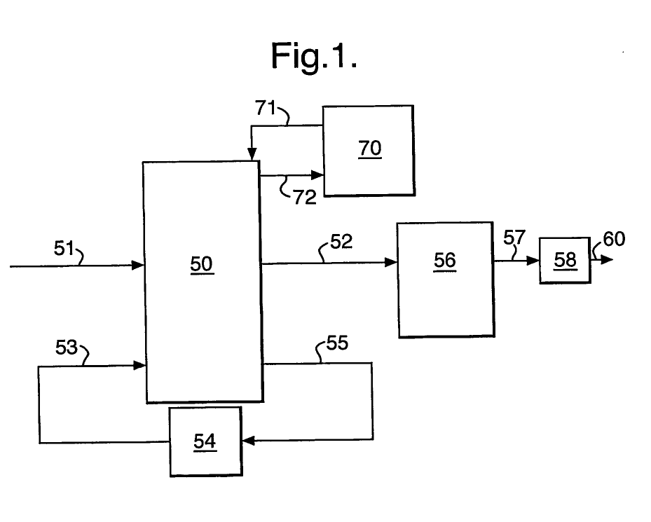

FIG. 1 shows an encoder for converting m-bit information words to n-bit code words comprising a converter 50 connected to a bus 51 of width m bits for receiving m-bit information words and to a bus 52 of width n bits for delivering the converted n-bit code words. In this example, m is 8 and n is 16.

Furthermore, the converter 50 is connected to a bus 53 of width s-bits for receiving an encoder present state value that indicates the instantaneous coding state and to a bus 55 of width s-bits for delivering the encoder next state value. In this instance, the number of possible encoder states is 4, so s is 2.

The s-bit present state value is stored by a buffer memory 54 comprising, for example, s flip-flops. The buffer memory 54 is connected to bus 55 for receiving the next state value from the converter 50 and to bus 53 for delivering the present state value currently stored in the buffer memory 54.

In order to be able to select which one of the 4 n-bit code words to deliver for a given information word, converter 50 is also connected to computing and selection device 70 via busses 71 and 72. Computing and selection device 70 determines which of the 4 n-bit code words should be delivered to n-bit bus 52 as will be described later.

Converter 50 outputs the n-bit code word onto bus 52 and the s-bit next state value onto bus 55 that correspond to the m-bit information word on bus 51, the s-bit present state value on bus 53 and the selection value on bus 71. To do this the converter 50 may comprise a combinatorial logic circuit for producing the necessary n-bit code word and s-bit next state value outputs from the m-bit information word and s-bit present state value.

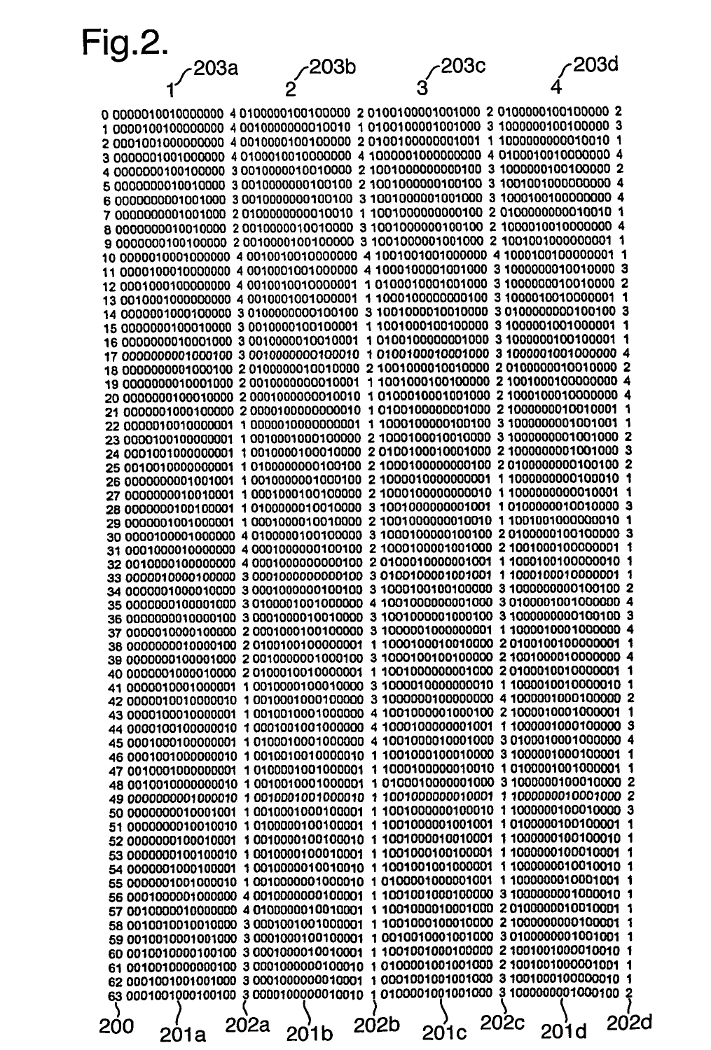

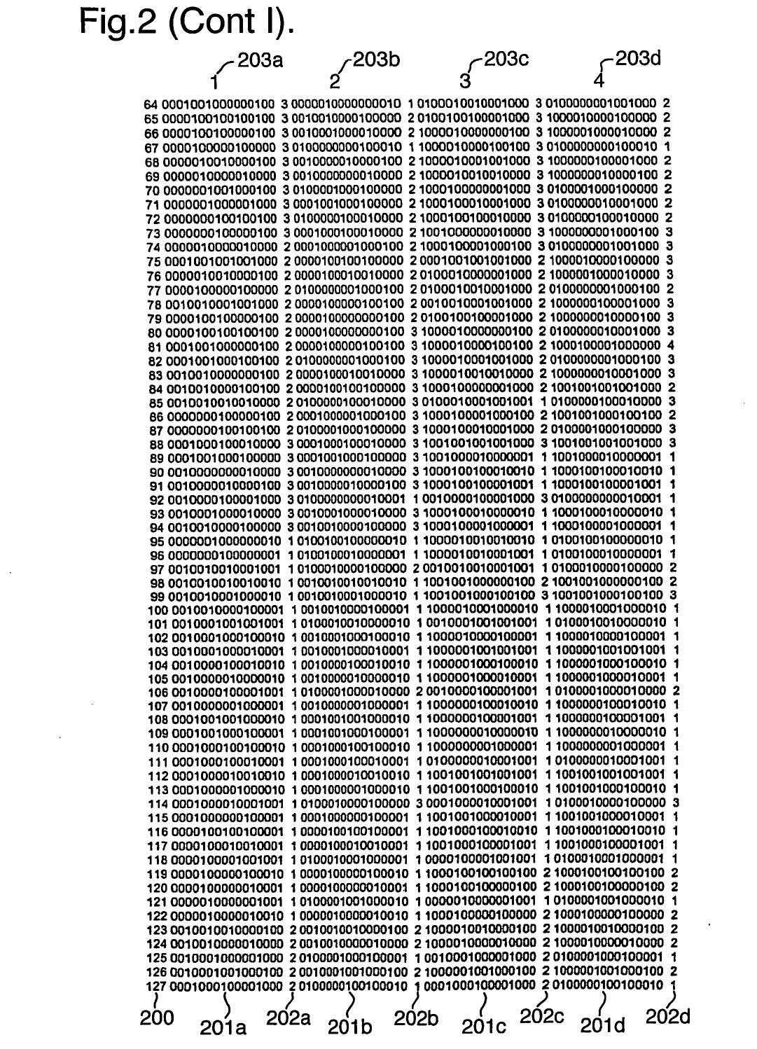

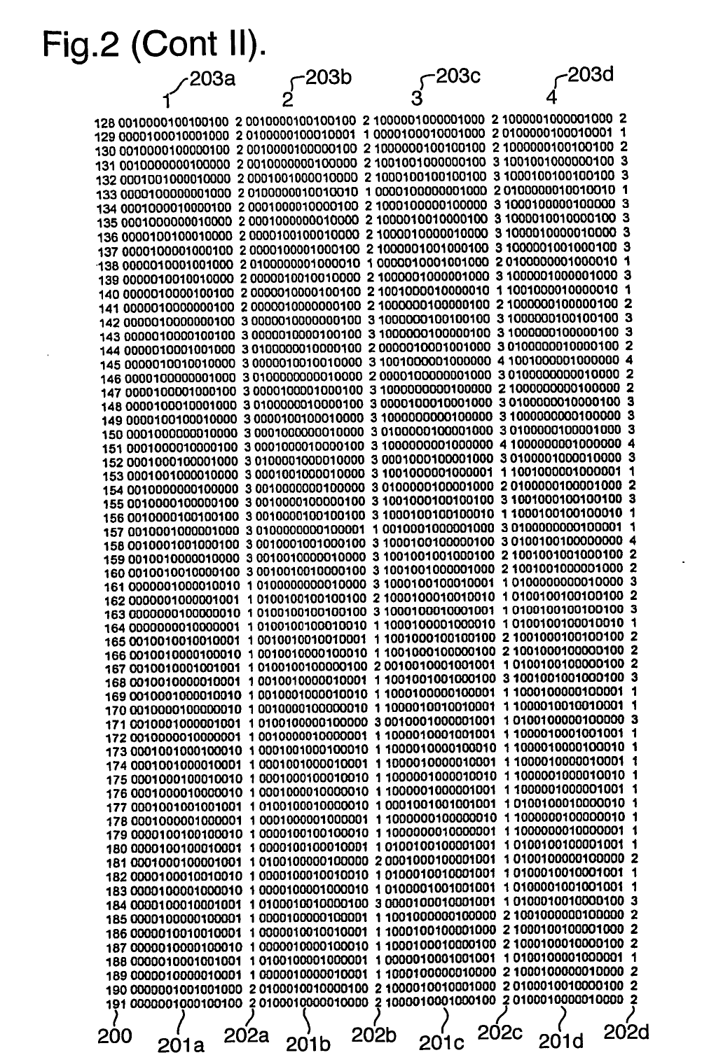

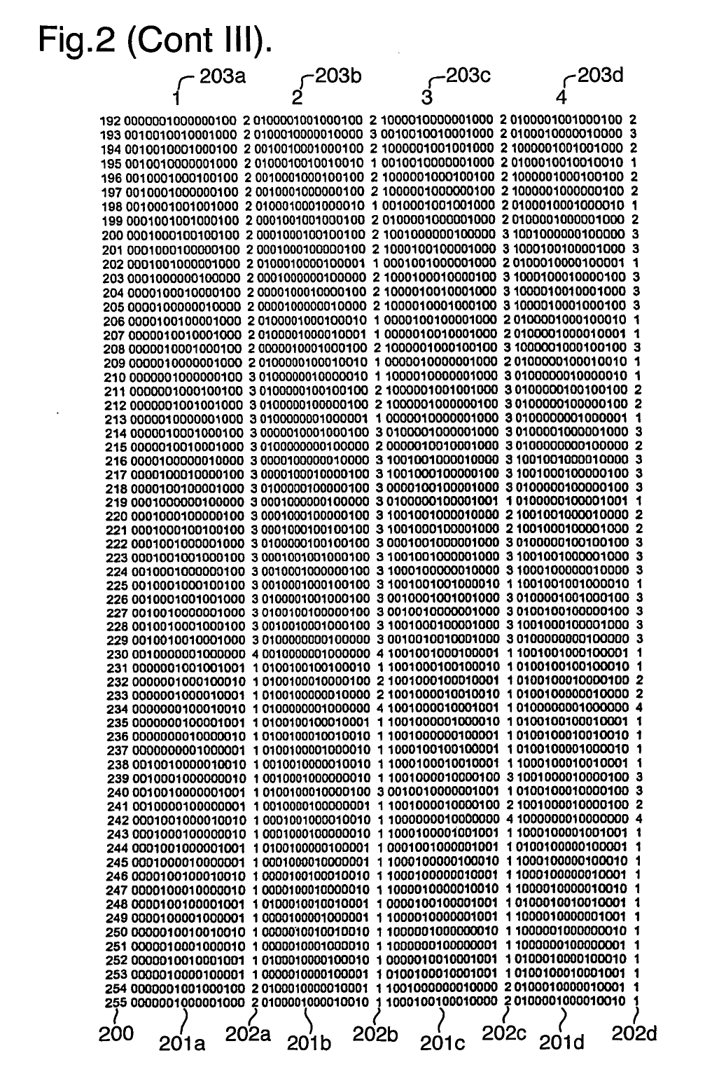

Alternatively, converter 50 may comprise a read only memory (ROM) addressed by busses 51, 53 and 71 and containing the information words and next state values. Essentially, the ROM in converter 50 will contain the contents of the table shown in FIG. 2. In this way, when an information word, present state value and selection value appear on busses 51, 53 and 71 respectively, the ROM can fetch the associated information word and next state value and place them on busses 52 and 55 respectively.

Bus 52 is connected to the parallel inputs of a parallel-to-serial converter 56, which converts the code words received from the converter 50 via bus 52 to a serial bit stream to be supplied over signal line 57 to a modulator circuit 58. This converts the bit stream to a modulated signal to be delivered over line 60.

Typically, the modulator 58 will convert the bit stream received over signal line 57 to a non-return to zero (NRZ) code in a conventional way. As such, the modulator circuit 58 may be, for example, a modulo-2 integrator.

For the purpose of synchronization of the operations to be performed, the coding device shown in FIG. 1 comprises a clock generating circuit (not shown) for generating clock signals for controlling the parallel/serial converter 58 and for controlling the loading of the buffer memory 54.

Each information word corresponds to four code words and four next state values. The present state value is used to select one code word and next state value from the set of four. However, the converter can supply one of the other three code words corresponding to the information word provided that certain constraints are met.

These are a run length constraint and a bit structure constraint. The run length constraint is typically a (d, k) constraint which has already been described with reference to the prior art.

The bit structure constraint arises due to the requirement to be able to distinguish between code words belonging to states 2 and 3 as will be described later. In this case, this is done by inspection of the first and thirteenth bit of the code words. A code word belonging to state 2 has its first and thirteenth bits both set equal to zero whilst at least one of the first and thirteenth bits of a code word belonging to state 3 is equal to one.

Thus, if it is desired to substitute a code word from another state for one in state 2 or state 3, it is necessary to meet the bit structure constraint. Hence, the first and thirteenth bits of the substitute code word must be equal to zero to replace a code word belonging to state 2 and at least one of the first and thirteenth bits of the substitute code word must be equal to one to replace a code word belonging to state 3.

The final selection amongst suitable code words is made on the basis of dc control. That is to say that the code word that will cause the dc content of the modulated bit stream on signal line 60 to be closest to zero will be chosen.

For the purpose of selection between code words on the basis of the run length constraint, the bit structure constraint and dc control, computing and selection device, 70, is employed. On receipt of an information word via bus 51, converter 50 transmits all four code words corresponding to the information word as well as the present state value to computing and selection device 70 via bus 72. Computing and selection device 70 stores these in a local memory.

Computing and selection device 70 comprises means for determining whether each of the set of four code words meets the run length constraint and, if appropriate, the bit structure constraint.

Typically, the means for determining whether the run length constraint is met comprise a combinational logic circuit for counting the total number of binary zeros at the beginning of each of the four code words and at the end of the preceding word and providing a predetermined output if the total number lies within the run length range, i.e. the (d,k) constraint is met.

The means for determining whether the bit structure constraint is met will typically comprise another combinational logic circuit. For example, a NOR gate may be configured to produce a binary one output if, and only if, both the first and thirteenth bits of a code word are binary zeros.

For those code words that meet the run length and bit structure constraints, computing and selection device 70 then determines the low-frequency content for each and selects the code word that best will cause the modulated bit stream on signal line 60 to be closest to zero. In a preferred embodiment of the computing device, the running digital sum is used for establishing the low-frequency content of the modulated signal.

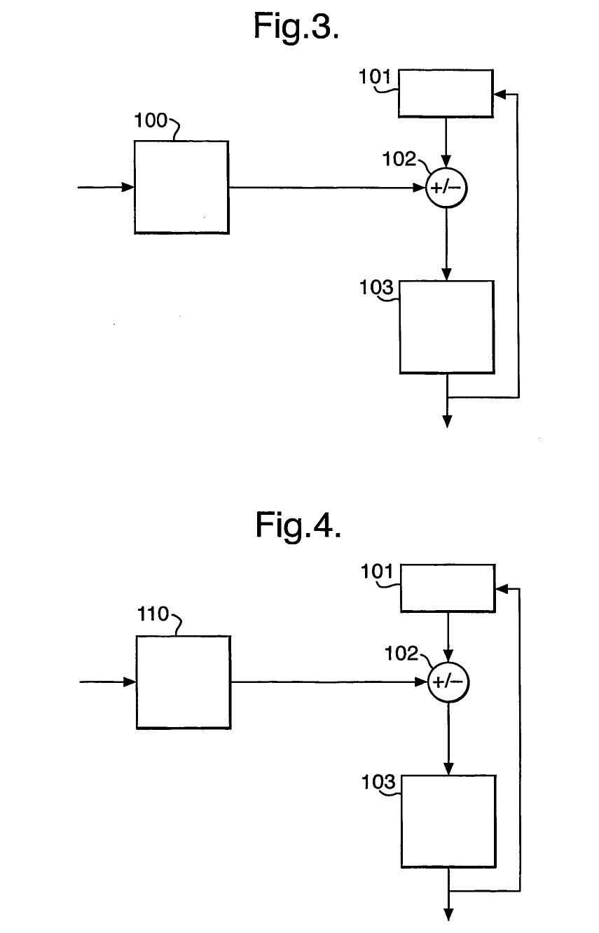

The running digital sum can be determined in many ways. A first implementation uses a binary up/down counter 100 as shown in FIG. 3. The bits of the code word are presented to the counter 100 as a serial bit stream with the most significant bit first. If the up/down counter 100 detects either a binary one or zero in the bit stream then the count value is incremented or decremented as appropriate and if the up/down counter 100 detects a binary one in the bit stream then the direction of counting is reversed after the count value has been incremented or decremented as appropriate. The running digital sum and a direction flag for indicating whether the running digital sum is increasing or decreasing are stored in an accumulator 101. If the direction flag indicates that the running digital sum is increasing then the running digital sum is added, using adder/subtracter 102, to the count values produced by the up/down counter for each code word presented to it. Alternatively, if the direction flag indicates that the running digital sum is decreasing then the count values produced by the up/down counter for each code word presented to it are subtracted from the running digital sum by adder/subtracter 102. The results of the addition or subtraction are stored in registers 103. When a code word has been chosen the appropriate result from registers 103 is used to update accumulator 101 with the new running digital sum.

Another implementation uses a memory 110 in place of up/down counter 100 as shown in FIG. 4. This memory 110 stores, in a look up table, an individual running digital sum and a direction change flag for each code word. As before, the running digital sum and a direction flag for indicating whether the running digital sum is increasing or decreasing are stored in accumulator 101. If the direction flag indicates that the running digital sum is increasing then the running digital sum is added, using adder/subtracter 102, to the individual running digital sums supplied by memory 110 for each code word presented to it. Alternatively, if the direction flag indicates that the running digital sum is decreasing then the individual running digital sums supplied by memory 110 for each code word presented to it are subtracted from the running digital sum by adder/subtracter 102. The results of the addition or subtraction are stored in registers 103. When a code word has been chosen the appropriate result from registers 103 is used to update accumulator 101 with the new running digital sum. If the direction change flag associated with the chosen code word is set then the value of the direction flag is inverted. Hence, whether the running digital sum increases or decreases is determined by the present values of the direction flag and the direction change flag.

The chosen code word is indicated to converter 50 via bus 73 and converter 50 then outputs the code word and next state value onto busses 52 and 55 respectively as already described.

FIG. 2 shows the table used by converter 50 to determine which 16-bit code word and new state value to deliver for each 8-bit information word and present state value. The code words and next state values have been assigned in such a manner that the predetermined run length or (d, k) constraint is met. Thus, if the code words are chosen as indicated only by the information words and next state values, then the encoded bit stream will meet the run length constraint although no control of the dc content is then possible. However, the disparity of the modulated words associated with an information word are substantially opposite so that the effect on the running digital sum when substituting code words from different states is significant.

The table comprises a column 200 for storing the 2^{m} or 256 possible 8-bit information words in lexicographical order and a pair of columns 201a-d, 202a-d containing the corresponding code words and next state values for each present state value 203a-d.

There are code words that correspond uniquely to an information word, known as code words of the first type, and code words that are duplicated and appear repeatedly for the same present state value. These are known as code words of the second type. However, the next state values always differ between these duplicate code words. For example, it can be seen from FIG. 2 that in column 201a, the code words for information words 6 and 7 are identical but the next state values differ, being 3 and 2 respectively.

The states can also be split into two groups. States 1 and 4 belong to the first group of states whilst states 2 and 3 belong to the second group of states. The second group of states consist of next state values that are required, when decoding, to determine which information word a duplicate code word corresponds to. Thus, with the example given above, it is possible to determine whether the information word is 6 or 7 by determining whether the following code word belongs to states two or three. This is determined by the unique bit structure of these states as already described.

Each time a conversion is to take place of an information word, given the encoder is in state 1 or 4, that particular code word is selected from the 4 code words corresponding to the information word whose juxtaposition with the previously written code words satisfies the prescribed run length or (d, k) constraint and for which the running digital sum is nearest zero. In this manner the DC voltage level of the modulated signal is maintained at a substantially constant level close to zero and the low-frequency components are kept as small as possible.

When the encoder is in state 1 or 4, the code word converted immediately prior to entering this state is of the first type. By definition, during decoding, the state 1 or 4 code word does not need to be observed to uniquely establish the information word associated with the prior code word. Hence, the encoder can choose from any of the four code words associated with the given information word as long as the run length or (d, k) constraint is satisfied.

The following example clarifies the encoding and selection procedure. Let the encoder state be 1 (or 4), and let the number of trailing binary zeros of the previously transmitted code word be 5. If the information word, i=0 then all 4 code words associated with byte i=0, namely 0000010010000000, 0100000100100000, 0100100001001000, and 0100000100100000 (see FIG. 2) can be collected into a selection set S as the juxtaposition of all code words with the previous code word does not violate the d=2 and k=10 run length constraint.

If, on the other hand, the number of trailing 0's of the previous code word had been 7, then only the three code words 0100000100100000, 0100100001001000, and 0100000100100000 would have been collected into the selection set S since the code word 0000010010000000 would violate the k=10 constraint as the number of consecutive binary zeros (the 7 trailing binary zeros and 5 leading binary zeros) exceeds 10.

If the number of members of the selection set S exceeds unity, then the code word selector chooses that code word from the ones available in the selection set that is most beneficial to the low-frequency content. If the selection set contains only one index member, there is no choice but to transmit that single code word.

Code words in states 2 and 3 have been compiled in such a way that observation of the first and thirteenth bit of the code words belonging to State 2 and 3 suffices to establish the related state of said code word.

Specifically, code words in State 2 have both the 1st and 13th bit equal to 0, while code words in State 3 do not have both the 1st and 13th bit equal to 0. A code word of the second type is always followed by a code word from the second group of states, that is state 2 or state 3. Thus, an information word associated with a code word of the second type can be uniquely decoded by observing the present code word and the first and thirteenth bits of the upcoming code word.

Each time a conversion is to take place of an information word, given the encoder is in State 2, that particular code word is selected from the 4 code words associated with the information word whose juxtaposition with the previously written code words satisfies the prescribed (d, k) constraint and bit structure constraint, that is that both the first and thirteenth bits are equal to 0 and for which the running digital sum is nearest zero.

Similarly, each time a conversion is to take place of an information word, given the encoder is in State 3, that particular code word is selected from the 4 code words associated with the information word whose juxtaposition with the previously written code words satisfies the prescribed (d, k) constraint and bit structure constraint, that is that both the first and thirteenth bits are not equal to 0 and for which the running digital sum is nearest zero.

The following example clarifies the encoding and selection procedure. Let the encoder state be equal to 2, and let the number of trailing zeros of the previously transmitted code word be 5. If the information word, i=0 then all 4 code words associated with i=0, namely 0000010010000000, 0100000100100000, 0100100001001000, and 0100000100100000 (see FIG. 2) satisfy that their juxtaposition with the previous code word does not violate the d=2 and k=10 constraint.

As the present state equals 2, a candidate code word must have both the first and thirteenth bits equal to 0, so the selection set S comprises two members, namely 0000010010000000 and 0100000100100000.

If the number of members of the selection set exceeds unity, then the code word selector chooses that code word from the members available in the selection set that is most beneficial to the low-frequency content. If the selection set contains only one member, there is no choice but to transmit that single code word.

Although the size of the selection set depends on the run length constraint, which implies that a selection set of more than one code word is not available for each information word under all circumstances, it is possible to influence the running digital sum nevertheless. In practice this appears to be sufficient to ensure that low-frequency components are absent in the modulated signal.

It is preferable to include in the sets of code words associated with an information word pairs of code words for which the change caused in the running digital sum is greatest, i.e. pairs of code words whose associated modulated signals have opposite disparity, where the disparity is defined as the difference between the number of binary zeros and binary ones in the modulated signal.

1. A method for converting a succession of data words into an output bit stream comprising a succession of code words using a table of code words and associated next state values and in which for each data word the table provides a code word and associated next state value for each of a plurality of present state values, the code words being either of a first type that correspond to only one data word or of a second type that correspond to more than one data word, the next state value associated with each code word of the second type belonging to one of a first group of states, the next state values ensuring that adjacent code words chosen in accordance with the next state values satisfy a run length constraint, and wherein code words belonging to the first group of states can be identified by a unique bit structure, the method comprising:
a. retrieving a data word;
b. selecting the code words corresponding to the data word for each of the plurality of present state values which meet the run length constraint and, if the present state value belongs to the first group of states, which also match the unique bit structure of the present state value;
c. selecting, from the code words selected in step b, the code word that will cause the dc content of the output bit stream to be closest to zero; and,
d. placing the code word selected in step c in to the output bit stream.

2. A method according to claim 1, wherein the number of present state values and next state values is 4.

3. A method according to claim 2, wherein the present state values and next state values are in the range 1 to 4.

4. A method according to claim 3, wherein the first group of states comprises the present state and next state values 2 and 3.

5. A method according to claim 4, wherein the unique bit structure of code words corresponding to present state values 2 or 3 is that at least two bits have a predetermined value.

6. A method according to claim 5, wherein the unique bit structure of code words corresponding to present state value 2 is that both the first and thirteenth bits are zero.

7. A method according to claim 5, wherein the unique bit structure of code words corresponding to present state value 3 is that both the first and thirteenth bits are not zero.

8. A method according to claim 1, wherein the length of a data word is eight bits.

9. A method according to claim 1, wherein the length of a code word is sixteen bits.

10. A method according to claim 1, wherein the run length constraint is that between each binary one of the output bit stream there is at least a first number of binary zeros and no more than a second number of binary zeros.

11. A method according to claim 10, wherein the first number is 2 and the second number is 10.

12. A method according to claim 1, wherein selection of the code word that will cause the dc content of the output bit stream to be closest to zero comprises calculating the running digital sum of the output bit stream and all code words meeting the run length constraint and, if the present state value belongs to the first group of states, matching the unique bit structure of the present state value.

13. A recording medium carrying a bit stream converted using a method according to claim 1.

14. A recording medium according to claim 13, wherein the recording medium is a Compact Disc (CD), Digital Versatile Disc (Dvp) or MiniDisc (MD)

15. An encoder for converting a succession of data words into an output bit stream comprising a succession of code words, the encoder comprising:
a. a data word input for receiving a data word;
b. a first memory for storing a table of code words and associated next state values and in which for each data word the table provides a code word and associated next state value for each of a plurality of present state values, the code words being either of a first type that correspond to only one data word or of a second type that correspond to more than one data word, the next state value associated with each code word of the second type belonging to one of a first group of states, the next state values ensuring that adjacent code words chosen in accordance with the next state values satisfy a run length constraint, and wherein code words belonging to the first group of states can be identified by a unique bit structure;
c. a selector for selecting the code words corresponding to the data word from the others of the plurality of present state values which meet the run length constraint and, if the present state value belongs to the first group of states, which also match the unique bit structure of the present state value;
d. a second memory for storing the code words selected in step c;
e. a running digital sum circuit for determining the running digital sum of the output bit stream and each of the code words stored in the second memory;
f. a selector for selecting that code word from the second memory that had the lowest running digital sum in step d; and,
g. an code word output for placing the code word in the output bit stream.

16. An encoder according to claim 15, wherein the running digital sum circuit comprises an up/down binary counter, the direction of counting of which is changed after detection of a binary one and the count value of which is incremented or decremented, as appropriate, by the detection of either a binary one or zero.

17. An encoder according to claim 15, wherein the running digital sum circuit comprises a memory storing a look up table having an individual running digital sum for each code word.

18. An encoder according to claim 17, wherein the look-up table also has a direction change flag for each code word.
